(19) United States
(12) Patent Application Publication
(10) Pub. No.: US 2008/0070420 A1
(43) Pub. Date: Mar. 20, 2008

(54) METHOD OF FABRICATING IMAGE SENSOR

(76) Inventor: Joo-Hyun Lee, Seoul (KR)

Correspondence Address: SHERR & NOURSE, PLLC, 620 HERNDON PARKWAY, SUITE 200, HERNDON, VA, 20170, US

(21) Appl. No.: 11/849,771

(22) Filed: Sep. 4, 2007

(30) Foreign Application Priority Data
Sep. 18, 2006 (KR) 10-2006-0090069

(51) Int. Cl. H01L 21/31

(52) U.S. Cl. 438/760; 257/E21.243

(57) ABSTRACT

A method of fabricating an image sensor is disclosed, by which etch damage and stress causing dislocation can be reduced in a manner of forming a liner oxide layer and performing thermal hardening simultaneously. A method of fabricating an image sensor according to embodiments may include etching a trench in a semiconductor substrate using a hard mask formed over the semiconductor substrate. A liner oxide layer may be formed within the trench and then densified. Dopant may be implanted into the liner oxide layer. The hard mask may be removed, and the trench may be filled with an insulator, and the insulator planarized.

The present application claims priority under 35 U.S.C. 119 to Korean Patent Application No. 10-2006-0090069, filed on Sep. 18, 2006, which is hereby incorporated by reference in its entirety.

### BACKGROUND

An image sensor converts an optical image into an electrical signal. Image sensors may be classified into complementary metal-oxide-silicon (CMOS) image sensors and charge coupled device (CCD) image sensors. The CCD image sensor may have better photosensitivity and noise characteristics compared with the CMOS image sensor, but may be difficult to fabricate in relatively large scale integration and has higher power consumption than CMOS. In contrast, the CMOS image sensor may have a simpler manufacturing process, leading to higher scale integration, and lower power consumption, compared with CCD image sensors.

Technology for manufacturing the CMOS image sensors has improved, CMOS characteristics have improved, and thus research into CMOS image sensors is ongoing. A pixel of the CMOS image sensor includes photodiodes for receiving light and CMOS components for controlling image signals received from the photodiodes. In the photodiodes, pairs of electrons and holes are generated according to the wavelength and intensity of light of red, green and blue input through color filters and an output signal varies depending on the amount of generated electrons, thereby sensing an image.

A CMOS image sensor may include a pixel region, in which photodiodes may be formed, and a peripheral circuit region for detecting signals generated by the pixel region. The peripheral circuit region may surround the pixel region.

In fabricating a CMOS image sensor, STI implantation may be carried out. This process is incompatible with a densification process to reduce stress after completion of gap-fill and CMP. If the densification is carried out, impurities injected by the STI implantation diffuse. Therefore, the device isolation layer fails to play a role as a barrier.

Thus, if the densification is not carried out, damage is caused by an etch process for forming the STI. And, stress attributed to the damage causes dislocation indicated by ‘A’ shown in FIG. 1. The dislocation occurs in the crystalline atomic arrangement. The abnormal dislocation may cause leakage currents (junction leakage current, off-leakage current) to affect the performance of the CMOS image sensor to the point of failure.

### SUMMARY

Embodiments relate to a method of fabricating an image sensor, and more particularly, to a method of preventing dislocations within a crystal lattice in a CMOS image sensor. Embodiments relate to a method of fabricating an image sensor, by which etch damage and stress causing dislocations can be reduced by forming a liner oxide layer and performing thermal hardening simultaneously.

A method of fabricating an image sensor according to embodiments may include etching a trench in a semiconductor substrate using a hard mask formed over the semiconductor substrate. A liner oxide layer may be formed within the trench and then densified. Dopant may be implanted into the liner oxide layer. The hard mask may be removed, and the trench may be filled with an insulator, and the insulator planarized.

In embodiments, the hard mask may include an oxide layer and a nitride layer stacked over the oxide layer. The hard mask may include a photoresist pattern. The etch may be dry etch using plasma. The plasma may use, for example, Cl₂ or HBr added to Cl₂. The plasma may include HBr and Cl₂ mixed together in a ratio of approximately 5:1. The hard mask may be removed, for example, by ashing and cleaning. The planarizing step may be performed by etchback.

In embodiments, the liner oxide layer may be formed by performing thermal oxidation over the substrate exposed by the etch. The liner oxide layer may be densified by thermal hardening. The thermal hardening process may include performing oxidation process over the substrate exposed by the etch to form the liner oxide layer; and performing annealing process over the substrate.

In embodiments, the oxidation process may use oxygen gas in the process chamber by approximately 1 to 5 standard liters per minute (SLM). The process chamber may be charging nitrogen gas as soon as the oxygen gas is discharged. The oxidation process may keep a process chamber at between approximately 600 and 800° C. for approximately ½ to 3 hours. The liner oxide layer may be formed of approximately 100 to 500 Å thick. The annealing process may use nitrogen gas in the process chamber by approximately 1 to 20 SLM. The annealing process may keep a process chamber at approximately 900 to 1,100° C. The liner oxide layer forming and densifying processes may be carried out simultaneously.

In embodiments, the dopant may include boron-series substance. The dopant may be injected into the liner oxide layer by STI (shallow trench isolation) implantation and the STI implantation is carried out at a BF-ion dose of approximately 1×10¹³ to 1×10¹⁴ atoms/cm² with 90 KeV.

### DRAWINGS

FIG. 1 is a picture of dislocation in an image sensor according to a related art.

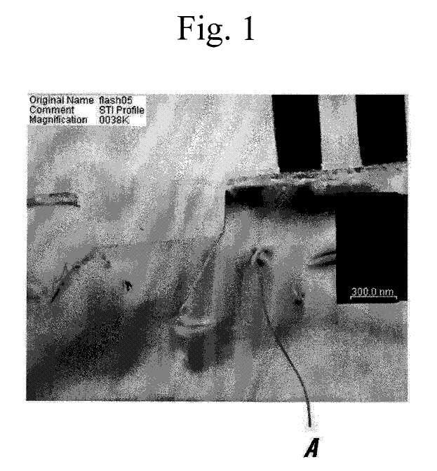

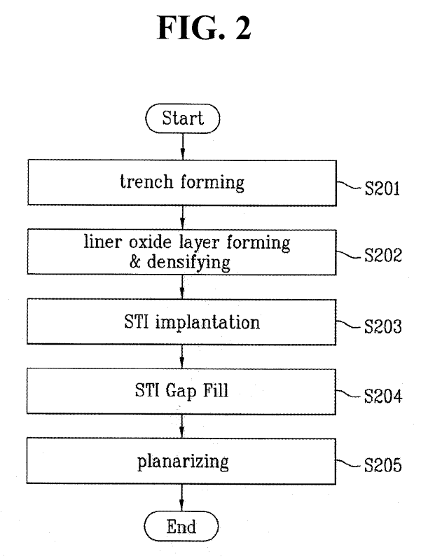

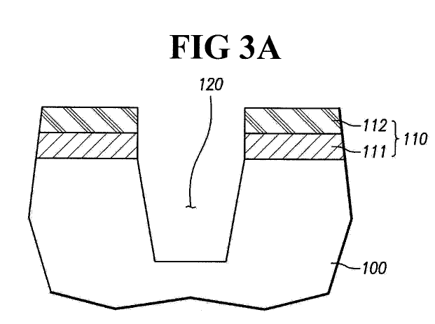

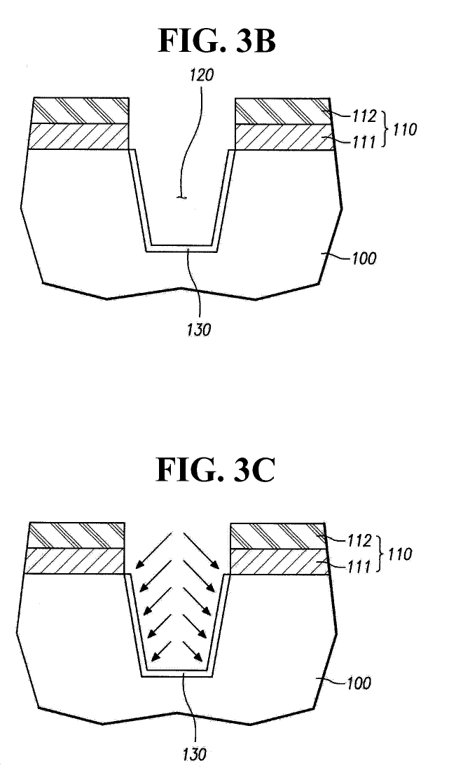

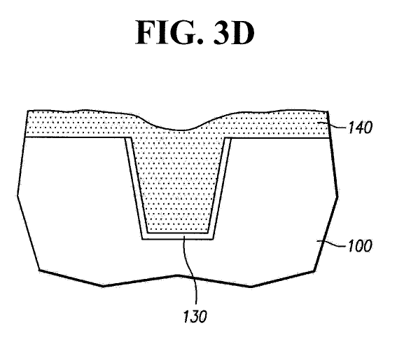

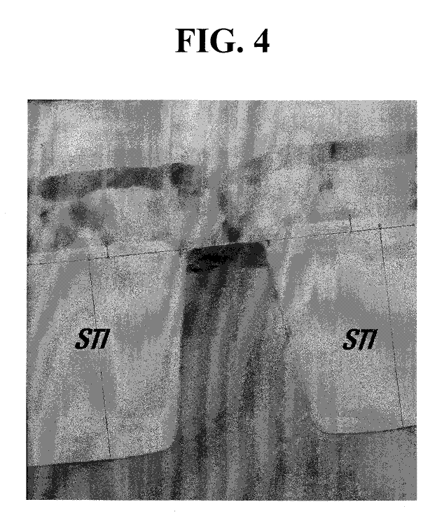

Example FIG. 2 is a flowchart of a method of fabricating an image sensor according to embodiments.

Example FIGS. 3A to 3D are cross-sectional diagrams for a method of fabricating an image sensor according to embodiments.

Example FIG. 4 is a picture of STI in an image sensor according to embodiments.

### DESCRIPTION

Example FIG. 2 is a flowchart of a method of fabricating an image sensor according to embodiments, and example FIGS. 3A to 3D are cross-sectional diagrams for a method of fabricating an image sensor according to embodiments. Referring to example FIG. 3A, a trench 120 may be dry etched in a semiconductor substrate 100 using plasma (S201). A stacked layer including an oxide layer 111 and a nitride layer 112 or a photoresist pattern may be used as a hard mask 110. The plasma dry etch uses Cl₂ plasma or Cl₂+HBr plasma. In particular, a quantity of oxygen used for plasma is selectively adjusted to control a trench angle. According to embodiments, reactant gas used for the plasma may include HBr and Cl₂ mixed together in a ratio of approximately 5:1.

Subsequently, a liner oxide layer 130 may be formed over an inner sidewall of the trench 120. Thermal hardening may then be carried out for densification of the liner oxide layer 130 (S202). Referring to example FIG. 3B, oxidation is carried out over the semiconductor substrate 100 having the trench 120 to form a liner oxide layer. In particular, the oxidation may be carried out by introducing oxygen gas into a process chamber at approximately 1 to 5 SLM. The process chamber may be kept at approximately 600 to 800° C. for approximately ½ to 3 hours. Under these conditions, the liner oxide layer 130 may become approximately 100 to 500 Å thick. Subsequently, nitrogen gas may be introduced into the process chamber at approximately 1 to 20 SLM as soon as the oxygen gas is discharged from the process chamber. Thermal hardening may then be carried out by annealing at approximately 900 to 1,100° C.

Thus, by forming the liner oxide layer 130 and performing the thermal hardening simultaneously, it is able to reduce etch damage and stress that may cause the dislocations. The liner oxide layer 130 plays a role as a buffer layer to prevent penetration of impurities in subsequent processes.

Referring to example FIG. 3C, boron-series dopant may be injected by performing STI implantation over the thermo-hardened liner oxide layer 130. For instance, the STI implantation may be carried out at a dose of approximately 1×10¹³ to 1×10¹⁴ BF-atoms/cm² with an energy of 90 KeV. Ashing and cleaning may then remove the hard mask 110 including the oxide layer 111 and the nitride layer 112.

Referring to example FIG. 3D, a gap-fill process may be carried out to fill the trench 120 with a silicon oxide layer 140. Planarization may then be carried out over the whole surface of the semiconductor substrate 110, by etchback for example. A surface of the insulating layer 140 is planarized (S205). The planarization may be performed by CMP (chemical mechanical polishing). Embodiments form the liner oxide layer 130 and perform thermal hardening thereon, thereby reducing the etch damage and stress that may cause the dislocation. Embodiments are advantageous in fabricating an image sensor, as shown in example FIG. 4, having an STI region free from dislocations.

Accordingly, embodiments may provide the following effects or advantages. Embodiments form a liner oxide layer and densify the liner oxide layer, thereby reducing etch damage and stress that may cause dislocations. Embodiments may reduce the number of processes required, thereby reducing cost of image sensor fabrication.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
etching a trench in a semiconductor substrate using a hard mask formed over the semiconductor substrate;
forming a liner oxide layer within the trench;
densifying the liner oxide layer;
implanting dopant into the liner oxide layer;
removing the hard mask;
filling the trench with an insulator; and
planarizing the insulator.

2. The method of claim 1, wherein the hard mask comprises an oxide layer and a nitride layer stacked over the semiconductor substrate.

3. The method of claim 1, wherein the hard mask comprises a photoresist pattern.

4. The method of claim 1, wherein the trench is dry etched using plasma.

5. The method of claim 4, wherein the plasma uses one of Cl₂ and HBr added to Cl₂.

6. The method of claim 4, wherein the plasma includes HBr and Cl₂ mixed together in a ratio of approximately 5:1.

7. The method of claim 1, wherein the liner oxide layer is formed by thermal oxidation on the substrate exposed by said etching the trench.

8. The method of claim 1, wherein the liner oxide layer is densified by a thermal hardening process.

9. The method of claim 8, wherein the thermal hardening process comprises:
performing oxidation process on the substrate exposed by the etching to form the liner oxide layer; and
performing an annealing process on the substrate.

10. The method of claim 9, wherein the oxidation process uses oxygen gas in the process chamber at approximately 1 to 5 standard liters per minute.

11. The method of claim 10, wherein the process chamber charges nitrogen gas as soon as the oxygen gas is discharged from the process chamber.

12. The method of claim 9, wherein a process chamber is kept at approximately 600 to 800° C. for approximately ½ to 3 hours during the oxidation process.

13. The method of claim 9, wherein the liner oxide layer is approximately 100 to 500 Å thick.

14. The method of claim 9, wherein the annealing process uses nitrogen gas in the process chamber at approximately 1 to 20 standard liters per minute.

15. The method of claim 9, wherein a process chamber is kept at approximately 900 to 1,100° C. during the annealing process.

16. The method of claim 1, wherein the liner oxide layer forming and densifying steps are simultaneously carried out.

17. The method of claim 1, wherein the dopant comprises a boron-series substance.

18. The method of claim 1, wherein the dopant is injected into the liner oxide layer by a shallow trench isolation implantation process and wherein the shallow trench isolation implantation process uses a BF-ion dose of approximately 1×10¹³ to 1×10¹⁴ BF-atoms/cm² at an energy of 90 KeV.

19. The method of claim 1, wherein the hard mask is removed by ashing process and cleaning processes.

20. The method of claim 1, wherein the planarizing step is performed by etch-back process.
